(19) United States
(12) Patent Application Publication
(10) Pub. No.: US 2018/0136270 A1
(43) Pub. Date: May 17, 2018

(54) PRODUCT SELF-TESTING METHOD

(71) Applicants: Inventec (Pudong) Technology Corporation, Shanghai (CN); INVENTEC CORPORATION, TAIPEI CITY (TW)

(72) Inventor: Tsung-Hao YANG, TAIPEI CITY (TW)

(21) Appl. No.: 15/475,151

(22) Filed: Mar. 31, 2017

(30) Foreign Application Priority Data
Nov. 15, 2016 (CN) 201611011838.6

(51) Int. Cl. G01R 31/28

(52) U.S. Cl. CPC G01R 31/2825

(57) ABSTRACT

A product self-testing method includes the steps of providing a device under test and a probe tool, connecting a plurality of test points of the device under test with the probe tool, turning on the device under test and executing a testing program on the device under test, outputting a voltage signal through at least one pin of the device under test and reading a voltage feedback signal from at least one another pin through the probe tool, and determining whether the voltage feedback signal is correct.

### RELATED APPLICATIONS

This application claims priority to Chinese Patent Application Serial Number 201611011838.6 filed Nov. 15, 2016, which is herein incorporated by reference.

### Technical Field

The present disclosure generally relates to a product self-testing method More particularly, the present disclosure relates to a product self-testing method using a probe tool.

### Background

In recent years, electronic devices are increasingly thin and light, and have more and more powerful data processing and communication capabilities. Therefore, the various types of electronic devices have become an indispensable part of our daily lives.

In general, many external factors, e.g., component damage, missing parts, short circuit, and open circuit and so on, inevitably exist and will affect the quality of products in the electronic device manufacturing process. Therefore, in order to effectively control the quality of the electronic device the electronic devices usually must be checked to reduce the detect rate and the quantity of the defective electronic devices.

However as the function of the motherboard of the electronic device becomes more and more complicated, how to effectively test the motherboard becomes more and more important. In the early production, an accurate and thorough test can reduce the assembly cost and also improve the product quality.

Therefore, the defective motherboard can be removed early if the motherboards of the electronic devices are completely tested, and not only the subsequent expensive repair process can be effectively avoided but also the yield of the final products can be improved.

### SUMMARY

One objective of the embodiments of the present invention is to provide a product self-testing method able to reduce the testing cost and the human requirement for testing the electronic devices, and further reduce the repairing cost for the defective electronic device.

To achieve these and other advantages and in accordance with the objective of the embodiments of the present invention as the embodiment broadly describes herein, the embodiments of the present invention provides a product self-testing method includes a product self-testing method includes the following steps. First, a device under test and a probe tool are provided. The probe tool are utilized to connect a plurality of test points of the device under test. The device under test is turned on and a testing program is executed on the device under test. A voltage signal is outputted through at least one pin of the device under test, and a voltage feedback signal is read from at least one another pin of the device under test through the probe tool. The testing program further determines whether or not the voltage feedback signal is normal. The testing result is recorded in the device under test according to the determination of the step of determining whether or not the voltage feedback signal is normal. In one exemplary embodiment, the testing result is recorded in a nonvolatile memory of the device under test.

In one embodiment, the device under test is a computer motherboard.

In one embodiment, the device under test is a mobile phone motherboard.

In one embodiment, the at least one pin is connected to a light emitting diode, and the at least one another pin reads the voltage feedback signal through the probe tool.

In one embodiment, the light emitting diode is a power indictor light emitting diode.

In one embodiment, the light, emitting diode is, a flash light emitting diode.

In one embodiment, the product self-testing method further includes the step of testing a vibrator or a step of simulating a power switch signal.

In one embodiment, the at least one pin includes a plurality of output pins to time-sharing output the voltage signal and the at least one another pin of the device under test time-sharing reads the voltage feedback signal through the probe tool, and vice versa.

Accordingly, the product self-testing method according to the present invention can utilize a probe tool to connect the test points of a device under test for testing the GPIO pins of the chipset of the device. Therefore, the product self-testing method according to the present invention can utilize a test program running on the device itself and the probe tool can automatically or manually connect to the device under test as well as the input and output pins are the GPIO pins of the device so that the device under test can automatically test itself without any other test computer required. Therefore, the cost of testing equipment and the required manpower can be significantly reduced. In addition, since the probe tool has to connect the corresponding test points while testing the device, the user cannot conduct the same test even if the user accidentally executes the testing program, and therefore the product elf-testing method according to the present invention can effectively reduce the trouble in use. Furthermore, after the device under test completes the test, the test result can be stored in the memory thereof. Therefore, in the subsequent process, such as the maintenance process, the test result can be read directly from the memory of the device so that the maintenance time and cost can be effectively reduced.

### BRIEF DESCRIPTION OF THE DRAWINGS

The foregoing aspects and many of the attendant advantages of this invention will be tore readily appreciated as the same becomes better understood by reference to the following detailed description, when taken in conjunction with the accompanying drawings, wherein:

FIG. 1 illustrates a circuit diagram for a product self-testing method according to an embodiment of the present invention; and

FIG. 2 illustrates a flowchart of a product self-testing method according to an embodiment of the present invention.

### DETAILED DESCRIPTION OF THE PREFERRED EMBODIMENT

The following description is of the best presently contemplated mode of carrying out the present disclosure. This description is not to be taken in a limiting sense but is made merely for the purpose of describing the general principles of the invention. The scope of the invention should be determined by referencing the appended claims.

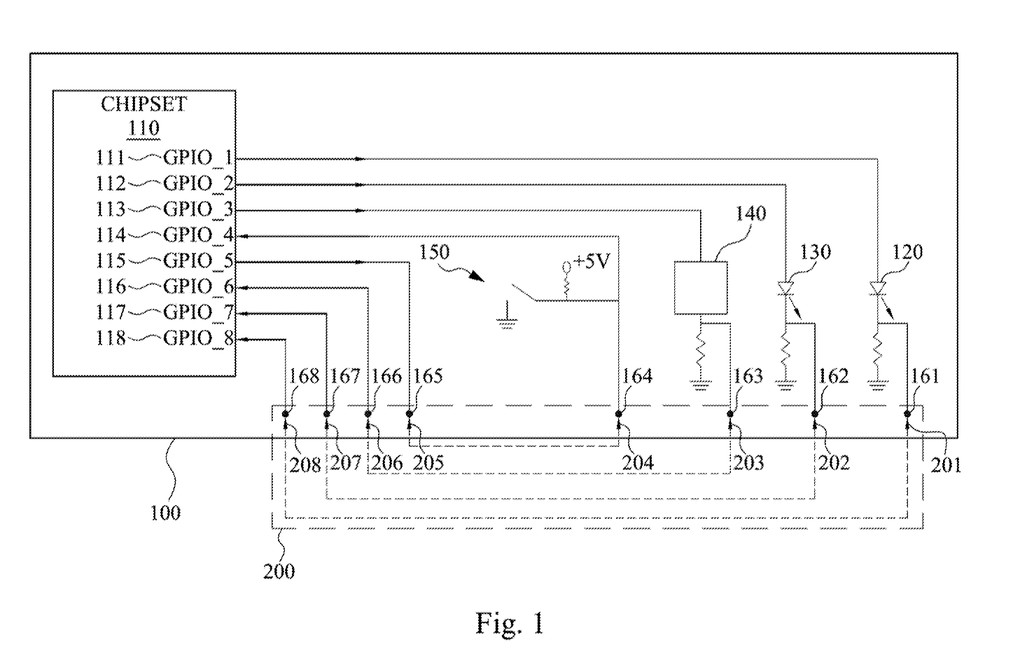

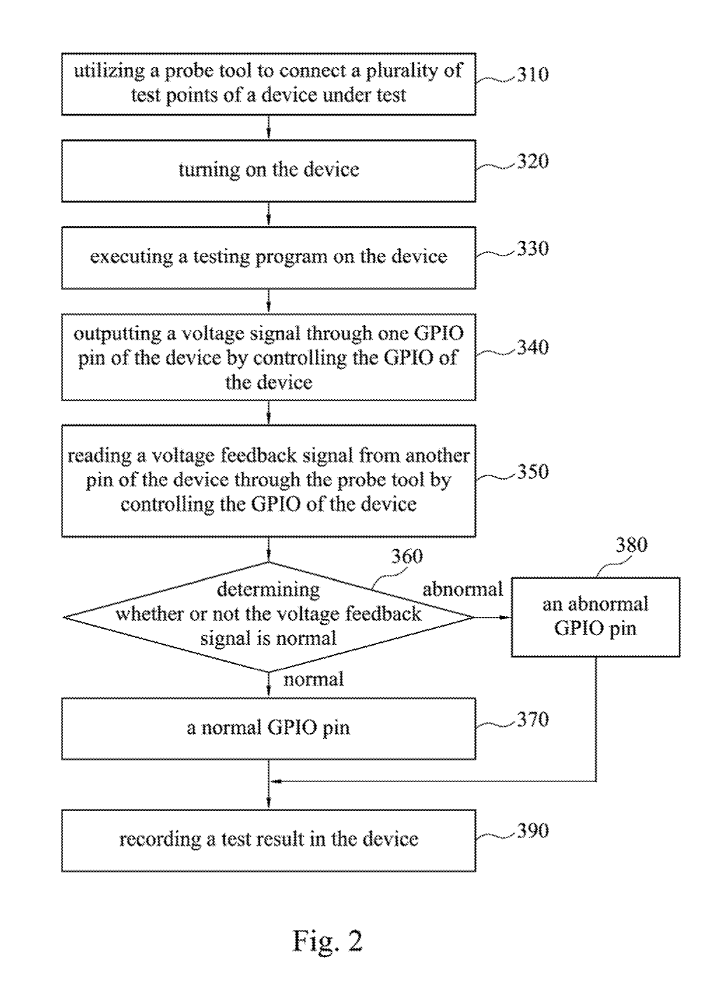

Refer to FIGS. 1 and 2. FIG. 1 illustrates a circuit diagram for a product self-testing method according to an embodiment of the present invention, and FIG. 2 illustrates a flowchart thereof.

As depicted in FIG. 1, the device under test 100, e.g. a motherboard of a computer or a mobile phone, includes a chipset 110, having a plurality of General-purpose input/output (GPIO) pins, for example, a first pin 111, a second pin 112, a third pin 113, a fourth pin 114, a fifth pin 115, a sixth pin 116, a seventh pin 117 and an eighth pin 118.

In one embodiment, the first pin 111 connects to a light emitting diode (LED) 120, e.g. a power indicator LED, the second pin 112 connects to another LED 130, e.g. a flash LED, the third pin 113 connects to a vibrator 140, the fourth pin 114 connects to a power switch 150.

A probe tool 200 includes, for example, first probe 201, a second probe 202, a third, probe 203, a fourth probe 204, a fifth probe 205, a sixth probe 206, a seventh probe 207 and an eighth probe 208.

While a test of the device under test 100 is to be performed, the probes of the probe tool 200 are respectively connected the corresponding test points of the plurality of GPIO pins of the chipset 110. As depicted in FIG. 1, the first probe 201 of the probe tool 200 connects to the first test point 161 of the device under test 100, the second probe 202 connects to the second test point 162, the third probe 203 connects to third test point 163, the fourth probe 204 connects to the fourth test point 164, the fifth probe 205 connects to the fifth test point 165, the sixth probe 206 connects to the sixth test point 166, the seventh probe 207 connects to the seventh test, point 167 and the eighth probe 208 connects to the eighth test point 168.

Simultaneously referring to FIG. 2, in step 310, the probe tool 200 is utilized to connect the test points of the device under test 100. Subsequently, in step 320, the device under test 100 is turned on. In step 330, a testing program is executed in the device under test 100. The testing program controls the device under test 100 to output a voltage signal by way of one GPIO pin, in step 340. Then, in step 350, the device under test 100 controls the GPIO thereof to read a voltage feedback signal with another GPIO pin through the probe tool 200.

For example, as depicted in FIG. 1, the first pin 111 of the GPIO pins outputs a voltage signal having a high voltage to turn the LED 120 on, and the first probe 201 of the probe tool 200 is connected to the first test point 161 of the device under test 100. In addition, the first probe 201 and the eighth probe 208 are electrically connected together. The device under test 100 further controls the GPIO thereof to read a voltage feedback signal from the eighth pin 118 of the GPIO pins through the eighth probe 208 of the probe tool 200 and the eighth test point 168 of the device under test 100. If the voltage feedback signal demonstrates a correct voltage variation, e.g. a high voltage signal, it is meaning that the output of the first pin 111 is normal and the input of the eighth pin 118 is also normal. In step 360, the voltage feedback signal is utilized to determine whether or not the function of the first pin 111 and the eighth pin 118 is normal. Accordingly, the function of the first pin 111 and the eighth pin 118 is determined to be normal in step 370.

Conversely, if the voltage feedback signal fails to demonstrate a normal voltage variation at this time, for example, a continuous low voltage signal or an abnormal voltage, it is meaning that the output of the first pin 111 is abnormal, the input of the eighth pin 118 is abnonmal, or the function of the light emitting diode LED 120 is abnormal. In step 380, the function of the GPIO pins is determined to be abnormal.

Subsequently, in step 390, the test result is recorded in the device under test 100 for example, in a nonvolatile memory thereof. Therefore, the abnormal utilization of the defective product, e.g. a defective mobile phone motherboard, can be ruled out for subsequent process and the cost of subsequent assembly and maintenance can be effectively reduced.

Similarly, the voltage feedback signal of the seventh pin 117 can be utilized to determine whether or not the functions of the second pin 112, the seventh pin 117, and the LED 130 are normal according to the output voltage signal of the second pin 112

Furthermore, in the same manner, the voltage feedback signal of the sixth pin 116 can be utilized to determine whether or not the functions of the third pin 113, the sixth pin 116, and the vibrator 140 are normal according to the output voltage signal of the third pin 113. The fifth pin 115 can output a low voltage signal to simulate the action of the power switch 150, so that the fourth pin 114 can receive the>simulation signal input, and further determine the circuit is normal or not.

It is worth noting that the output pin and the input pin according to the present invention are not necessary one-to-one correspondence. For example, the first pin 111 and the second pin 112 can be electrically connected to the eighth pin 118 through the probe tool 200 and test these GPIO pins by the time-sharing program, and vice versa. It can effectively reduce the required quantity of the GPIO pins for testing the components of the device under test without departing from the spirit and scope of the present invention.

The product self-testing method according to the present invention utilizes a probe tool to connect the test points of a device under test for testing the GPIO pins of the chipset of the device. Therefore, the product self-testing method according to the present invention can utilize a test program running on the device under test itself without any other test computer required addition the input and output pins are the GPIO pins of the device under test and the probe tool can automatically or manually connected to the device under test so that the device under test can automatically test itself without any other test computer required. Therefore, the cost of testing equipment and the required manpower can be significantly red used.

In addition, since the probe tool has to connect the corresponding test points while testing the device under test, the user cannot conduct the same test even if the user accidentally executes the testing program, and therefore the product self-testing method according to the present invention can effective reduce the trouble in use. Furthermore, after the device under test independently completes the test, the test result can be stored in the memory thereof. Therefore, in the subsequent process, such as the maintenance process, the relevant test result can be read directly from the memory thereof so as to reduce the required time and cost of the mailenance process.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A product self-testing method, comprising:
providing a device under test and a probe tool;
utilizing the probe tool to connect a plurality of test points of the device under test;
turning on the device under test;
executing a testing program on the device under test;
outputting a voltage signal through at least one pin of the device under test;
reading a voltage feedback signal from at least one another pin of the device under test through the probe tool; and
determining whether or not the voltage feedback signal is normal.

2. The product self-testing method of claim 1, further comprising recording a testing result into the device under test according to determination of the step of determining whether or not the voltage feedback signal is normal.

3. The product self-testing method of claim 2, wherein the testing result is recorded in a nonvolatile memory of the device under test.

4. T he product self-testing method of claim 1, wherein the device under test is a computer motherboard.

5. The product self-testing method of claim 1, wherein the device under test is a mobile phone motherboard.

6. The product self-testing method of claim 5, wherein the at east one pin is connected to a light emitting diode, and the at least one another pin reads the voltage feedback signal through the probe tool.

7. The product self-testing method of claim 6, wherein the light emitting diode is a power indictor light emitting diode.

8. The product self-testing method of claim 6, wherein the light emitting diode is a flash light emitting diode.

9. The product self-testing method of claim 1, wherein the at least one pin comprises a plurality of output pins to time-sharing output the voltage signal, and the at least one another pin of the device under test time-sharing reads the voltage feedback signal through the probe tool.

10. The product self-testing method of claim 1, wherein the at least one another pin comprises a plurality of input pins, and the at least one pin time-sharing outputs the voltage signal and the input pins time-sharing read the voltage feedback signal through the probe tool.
